(19) United States
(12) Patent Application Publication
(10) Pub. No.: US 2025/0314712 A1
(43) Pub. Date: Oct. 9, 2025

(54) SYSTEM TO TEST POWER SUPPLIES WITH REDUCED THERMAL DISSIPATION

(71) Applicant: George Burcea, Ajax (CA)

(72) Inventor: George Burcea, Ajax (CA)

(21) Appl. No.: 18/630,215

(22) Filed: Apr. 9, 2024

(51) Int. Cl. G01R 31/40; H02M 1/00; H02M 1/32; H02M 3/158; H02M 7/217; H10N 10/13

(52) U.S. Cl. CPC G01R 31/40; H02M 1/0095; H02M 1/327; H02M 3/158; H02M 7/217; H10N 10/13

(57) ABSTRACT

The present disclosure provides a system and an electronic device for testing power sources. The system includes a first device under test (DUT) comprising a power source to provide an input power. The system further includes a first DC-to-DC converter to receive the input power and dynamically modify the input power. Further, the system includes a first controller to control one or more parameters of the first DC-to-DC converter and receive feedback from the first DC-to-DC converter. Further, the system includes a first thermoelectric converter to receive the modified input power from the first DC-to-DC converter and generate a first output of a set of outputs. The first output includes at least: a first hot output and a first cold output. Further, the system includes a mixer to receive the first output and combine the first hot output and the first cold output to modify power dissipation of the system.

### BACKGROUND OF THE INVENTION

This disclosure relates to the field of power supplies. More specifically, the present disclosure relates to a system and an electronic device for testing power supplies.

Conventional testing systems may employ active and passive test loads for assessing the functionality and performance of power supplies. Examples of such power supplies may include, but are not limited to, AC/DC converters, DC/DC converters, AC line transformers, batteries, dynamos, generators, and photoelectric sources. Further, the test loads used for testing the power supplies include, but are not limited to, resistors, capacitors, or other electronic loads. In particular, a test load is designed to mimic a device or a system that a power supply is intended to support. During testing, the power absorbed by the test load is converted into heat and dissipated into the environment. Such heat generation may contribute to reduced efficiency, increased energy consumption, increased temperature, and lower reliability of the testing systems.

Thus, there exists a need for advancements in the testing systems for power supplies to reduce heat dissipation and provide optimal power handling.

### SUMMARY OF THE INVENTION

In comparison with the conventional testing systems, the present disclosure provides a system and an electronic device for testing power supplies. The disclosed system may reduce heat dissipation and optimize power handling, thereby increasing the efficiency of the testing of a power supply.

In one aspect, a system for testing a power source is disclosed. The system includes a first device under test (DUT) of a set of DUTs including a power source to provide an input power. The system further includes a first DC-to-DC converter of a set of DC-to-DC converters to receive the input power and dynamically modify the input power drawn from the first DUT. Further, the system includes a first controller of a set of controllers to control one or more parameters of the first DC-to-DC converter according to a certain algorithm like constant current, constant power, constant resistance or other and receive feedback from the first DC-to-DC converter. Further, the system includes a first thermoelectric converter of a set of thermoelectric converters to receive the modified input power from the first DC-to-DC converter and generate a first output of a set of outputs. The first output includes at least of: a first hot output and a first cold output. Further, the system includes a mixer to receive the first output and combine the first hot output and the first cold output to cancel a temperature difference between the first hot output and the first cold output and minimize power dissipated by the system into the environment.

According to additional system embodiments, the first thermoelectric converter further controls heat flow from the first cold output to the first hot output.

According to additional system embodiments, the system further includes a first heatsink of a set of heatsinks connected with the first output of the first thermoelectric converter.

According to additional system embodiments, wherein the mixer receives a heated air stream and a cooled air stream from the first heatsink and combines the heated air stream and cooled air stream to cancel the temperature difference between the first hot output and the first cold output and minimize the power dissipated by the system into the environment.

According to additional system embodiments, the system further includes a second thermoelectric converter of the set of thermoelectric converters to generate a second output including at least of: a second hot output and a second cold output.

According to additional system embodiments, the first hot output of the first thermoelectric converter is connected to the second cold output of the second thermoelectric converter, and the first cold output of the first thermoelectric converter is connected to the second hot output of the second thermoelectric converter.

According to additional system embodiments, the first DC-to-DC converter dynamically modifies a voltage level of input power to a first level of the input power based on a specification of the first thermoelectric converter.

According to additional system embodiments, the first controller dynamically modifies the one or more parameters of the first DC-to-DC converter to obtain the first level of the input power.

According to additional system embodiments, the first DUT corresponds to a DC power source for providing a DC input power.

According to additional system embodiments, the first DUT corresponds to an AC power source for providing an AC input power.

According to additional system embodiments, the system further includes an AC-to-DC converter to convert AC input power to DC input power.

According to additional system embodiments, the set of controllers further provides real-time data associated with one or more performance metrics of the set of DUTs, the set of DC-to-DC converters, the set of thermoelectric converters, and the mixer.

In another aspect, an electronic device for testing the power supply is disclosed. The electronic device includes the first device under test (DUT) of a set of DUTs including a power source to provide an input power. The electronic device includes a first DC-to-DC converter of a set of DC-to-DC converters to receive the input power and dynamically modify the input power drawn from the first DUT. The electronic device further includes a first controller of a set of controllers to control one or more parameters of the first DC-to-DC converter and receive feedback from the first DC-to-DC converter. The electronic device includes a first thermoelectric converter of a set of thermoelectric converters to receive the modified input power from the first DC-to-DC converter and generate a first output of a set of outputs, wherein the first output includes at least of: a first hot output and a first cold output. Further, the electronic device includes a mixer to receive the first output and combine the first hot output and the first cold output to cancel a temperature difference between the first hot output and the first cold output and minimize power dissipated by the electronic device into the environment.

In yet another aspect, a system for testing power supply is disclosed. The system includes a first device under test (DUT) of a set of DUTs including a power source to provide input power. Further, the system includes a first DC-to-DC converter of a set of DC-to-DC converters to receive the input power and dynamically modify the voltage level of the input power to the first level of the input power. Further the system includes a first controller of a set of controllers to control one or more parameters of the first DC-to-DC converters and receive feedback from the first DC-to-DC converter. Further, the system includes the first thermoelectric converter of a set of thermoelectric converters to receive the first level of the input power from the first DC-to-DC converter and generate first output includes at least: a first hot output and a first cold output, wherein the first thermoelectric converter pumps heat from the first cold output to the first hot output. Further, the system includes a mixer to receive the first hot output, and the first cold output, and combine the first hot output and the first cold output to minimize power dissipation of the system by canceling the effect of heat pumping.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF FIGURES

Having thus described example embodiments of the invention in general terms, reference will now be made to the accompanying drawings, which are not necessarily drawn to scale, and wherein:

FIG. 1 illustrates a network environment in which a system for testing a power source is implemented, in accordance with an embodiment of the disclosure;

FIG. 2 illustrates an exemplary block diagram of the system of FIG. 1, in accordance with an embodiment of the disclosure;

FIG. 3 illustrates an exemplary system for testing the power source, in accordance with an embodiment of the disclosure;

FIG. 4 illustrates another exemplary system for testing the power source, in accordance with an embodiment of the disclosure;

FIG. 5 illustrates an exemplary system for testing the power source, in accordance with an embodiment of the disclosure;

FIG. 6 illustrates another exemplary system for testing the power sources, in accordance with an embodiment of the disclosure; and

FIG. 7 illustrates a block diagram of an electronic device for testing the power source, in accordance with some embodiment of the disclosure.

### DETAILED DESCRIPTION

In the following description, for purposes of explanation, numerous specific details are set forth in order to provide a thorough understanding of the present disclosure. It will be apparent, however, to one skilled in the art that the present disclosure may be practiced without these specific details. In other instances, systems and methods are shown in block diagram form only in order to avoid obscuring the present disclosure.

Some embodiments of the present disclosure will now be described more fully hereinafter with reference to the accompanying drawings, in which some, but not all, embodiments of the disclosure are shown. Indeed, various embodiments of the disclosure may be embodied in many different forms and should not be construed as limited to the embodiments set forth herein; rather, these embodiments are provided so that this disclosure will satisfy applicable legal requirements. Like reference numerals refer to like elements throughout. Also, reference in this specification to “one embodiment” or “an embodiment” means that a particular feature, structure, or characteristic described in connection with the embodiment is included in at least one embodiment of the present disclosure. The appearance of the phrase “in one embodiment” in various places in the specification are not necessarily all referring to the same embodiment, nor are separate or alternative embodiments mutually exclusive of other embodiments. Further, the terms “a” and “an” herein do not denote a limitation of quantity, but rather denote the presence of at least one of the referenced items. Moreover, various features are described which may be exhibited by some embodiments and not by others. Similarly, various requirements are described which may be requirements for some embodiments but not for other embodiments.

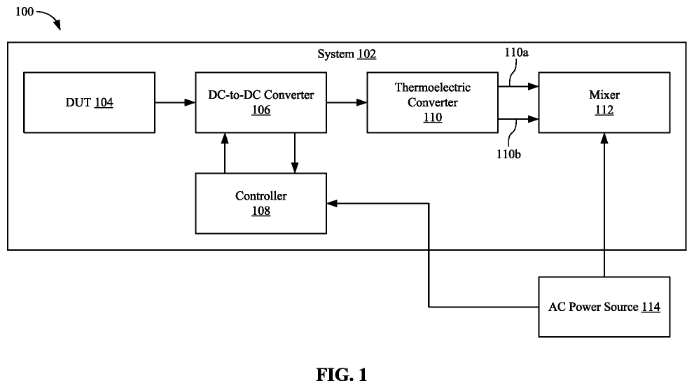

The embodiments are described herein for illustrative purposes and are subject to many variations. It is understood that various omissions and substitutions of equivalents are contemplated as circumstances may suggest or render expedient but are intended to cover the application or implementation without departing from the spirit or the scope of the present disclosure. Further, it is to be understood that the phraseology and terminology employed herein are for the purpose of the description and should not be regarded as limiting. Any heading utilized within this description is for convenience only and has no legal or limiting effect. Turning now to FIG. 1-FIG. 7, a brief description concerning the various components of the present disclosure will now be briefly discussed. Reference will be made to the figures showing various embodiments of a system for testing power sources with reduced heat dissipation.

FIG. 1 is a diagram that illustrates a network environment 100 in which a system 102 for testing a power source is implemented, in accordance with an embodiment of the disclosure. The system 102 may include a device under test (DUT) 104, a DC-to-DC converter 106, a controller 108, a thermoelectric converter 110, and a mixer 112. The system 102 is supplied from an AC power source 114.

The system 102 may correspond to a testing system that may test and validate power sources. In an embodiment, the power sources may correspond to, for example, power supplies, batteries, generators, dynamos, photoelectric sources, or solar panels. The system 102 may have the capability to simulate the power sources to check performance under test loads. Examples of such test loads may include, but are not limited to resistors, capacitors, or other electronic loads. The system 102 may be employed to evaluate the performance and characteristics of the power sources under various load conditions. Such power sources hereinafter may be referred to as Device Unter Test (DUT), for example, the DUT 104.

Further, the DUT 104 may be connected to the DC-to-DC converter 106. The DC-to-DC converter 106 may be a power electronic device that converts a voltage level of direct current (DC) to a different voltage level. Examples of a topology used to implement the DC-to-DC converter 106 may include, but are not limited to, buck converter, boost converter, buck-boost converter, and flyback converter. For example, the DC-to-DC converter 106 may receive an input voltage from the DUT 104 (such as a power source) and modify the received input voltage to another voltage level. The DC-to-DC converter 106 may modify the input voltage based on the voltage requirements of an electronic device connected therewith, such as the thermoelectric converter 110. For example, if the DUT 104 corresponds to a DC power source that outputs a DC power with a voltage level of 200 volts, the DC-to-DC converter 106 may step it down to 50V or step it up to 400V, as per the voltage requirements indicated by the thermoelectric converter 110.

The thermoelectric converter 110 may include a series of thermoelectric modules, which are made of pairs of n-type and p-type semiconductors connected electrically in series and thermally in parallel. The semiconductors are usually made of materials such as, but not limited to, bismuth telluride, lead telluride, or calcium manganese oxide, which have high thermoelectric efficiency. The thermoelectric modules are sandwiched between two metal plates, which function as a heat source and a heat sink. The heat source (a hot metal plate) provides a high temperature, and the heat sink (a cold metal plate) maintains a lower temperature. If a voltage is applied to the thermoelectric modules, one plate becomes hotter and the other becomes colder, creating a temperature difference that can be used for heating or cooling. The amount of power generated, or heat pumped depends on the current, the voltage, the temperature difference, and the number of modules. For example, if an applied voltage to the thermoelectric modules is high, then the temperature difference between the two metal plates becomes relatively high. For example, the thermoelectric converter 110 may have no moving parts, which makes it silent, reliable, and maintenance-free. The thermoelectric converter 110 may operate over a wide range of temperatures and heat sources. The thermoelectric converter 110 may be scaled up or down to suit different power requirements.

Further, the DC-to-DC converter 106 is connected to the controller 108. The controller 108 may be a device that may monitor and adjust one or more parameters of the DC-to-DC converter 106. The one or more parameters may include, but are not limited to, input voltage, output voltage, output current, and power.

In operation, the controller 108 is configured to receive a feedback from the DC-to-DC converter 106 about its performance and status, such as efficiency, temperature, and fault conditions. In an embodiment, the controller 108 may communicate with the DUT 104 and other devices in the system 102 via a communication interface, such as a serial port, a USB port, or a wireless connection. Further, the controller 108 may have a bidirectional communication link with the DC-to-DC converter 106. A feedback loop between the controller 108 and the DC-to-DC converter 106 facilitates a continuous exchange of information, providing the controller 108 with real-time data regarding the performance and status of the DC-to-DC converter 106. Such feedback may enable the controller 108 to ensure optimal functioning of the DC-to-DC converter 106 and by extension, the entire system 102.

Further, the DC-to-DC converter 106 may be connected to the thermoelectric converter 110. The thermoelectric converter 110 may correspond to a solid-state device that utilizes the thermoelectric effect to convert electrical energy into thermal energy. In an embodiment, the thermoelectric converter 110 may receive a modified input power, i.e., step-up DC of input or step-down DC of the input, from the DC-to-DC converter 106 and generate a first output. The first output may include a first hot output 110a or a first cold output 110b.

For example, the thermoelectric converter 110 may be a device that may produce a first output including the first hot output 110a and the first cold output 110b from electric power, depending on the direction of flow of the current. The thermoelectric converter 110 may work based on the Peltier effect states that when a current flows through a loop of two different conductors, one junction becomes hotter and the other becomes colder. This may be used for reducing the heat dissipated by the active load into the environment. Thereafter, the mixer 112 is configured to receive the first hot output 110a and the first cold output 110b of the thermoelectric converter 110. The mixer 112 may correspond to a device that combines the thermal energy from both sides (such as the first hot output 110a and first cold output 110b) of the thermoelectric converter 110 and dissipates the remaining thermal energy to the ambient air.

Further, the AC power source 114 may generate electrical power in the form of alternating current and provide input power to various electronic devices such as the controller 108 and the mixer 112 for performing operations. In an embodiment, the internal circuitry of the active load may be powered by the AC power source 114 via the housekeeping power supply. In another embodiment, the internal circuitry may be powered by auxiliary outputs of the DC-to-DC converter 106. In an embodiment, the DUT 104 may supply the necessary energy to drive the entire system 102, thereby providing a comprehensive evaluation of the performance of the DUT 104. The characteristics of the input power such as voltage and current may set baseline conditions for the subsequent stages of the process for testing of the DUT 104.

The system 102 is configured to test the DUT 104. The DUT 104 (referred to as the DUT 104) may correspond to a power source that may provide an input power to the active load for performing operations. In an example, the active load may be capable of operating in different operating modes with parameters at various settings, thereby enabling it to evaluate the performance of the DUT 104. Further, the power source may correspond to an Alternate current (AC) power source or a DC power source.

In an embodiment, the DUT 104 may correspond to the AC power source for providing the input power. In such a scenario, the DUT 104 may be, for example, an AC generator, an AC dynamo, and an AC power source. Further, the system 102 may include an AC-to-DC converter. The AC-to-DC converter may correspond to a power electronic device that converts a voltage level of AC power to a voltage level of DC power. Examples of a topology used to implement the AC-to-DC converter may include, but are not limited to, bridge rectifier, diode rectifier, switched-mode power supply, and linear regulator.

For example, the DUT 104 may provide AC input power. Further, the AC-to-DC converter may be configured to receive the AC input power and convert it into a DC input power. Thereafter, the DC input power may be transmitted to the DC-to-DC converter 106. The DC-to-DC converter 106 allows the testing of the DUT 104 providing AC input power to seamlessly interface with the AC power supply, broadening its compatibility to assess device that utilizes AC power or to evaluate the performance of power supplies under various input conditions.

In another embodiment, the DUT 104 may correspond to the DC power source. In such a scenario, the DUT 104 may be, for example, a DC generator, a DC dynamo, and a DC power source. Further, the DC-to-DC converter 106 may directly receive the DC input power from the DC power source (such as the DUT 104). Upon receiving the DC input power, the DC-to-DC converter 106 may modify the DC input power. The modification of the DC input power depends on the power requirement of thermoelectric converter 110.

In an embodiment, the DC-to-DC converter 106 dynamically modifies the voltage level of the input power to a first level of input power based on the specification of the thermoelectric converter 110. Such dynamic adjustment is finely tuned to align with specific requirements outlined in the specification of the thermoelectric converter 110. The DC-to-DC converters 106 adjust the voltage level of the input power received from the DUT 104 in order to match a precise requirement of the thermoelectric converter 110, thereby ensuring optimal performance and efficiency in the energy conversion process. In an example, the DC-to-DC converter 106 may receive the input power from the DUT 104 and dynamically adjust voltage levels or current levels to meet a specific load requirement for thermoelectric converter 110. The input power adjusted based on the voltage levels or current levels is referred to as the modified input power. The modified input power delivered to the thermoelectric converter 110 aligns precisely with its operational specifications, enabling a comprehensive and accurate assessment of its performance under varying conditions.

In an embodiment, the DC-to-DC converter 106 may be further connected to the controller 108. The controller 108 may be configured to control and optimize the one or more parameters governing the energy conversion. Operating in the closed loop configuration, the controller 108 may continuously monitor and adjust one or more parameters of the DC-to-DC converter 106 in real time. The controller 108 may dynamically adapt the DC-to-DC converter 106 to align its output with a load requirement imposed by the thermoelectric converter 110. Such close loop control mechanism enables the system 102 to maintain precise and desired electrical characteristics, irrespective of fluctuations at least one of the input power provided by the DUT 104, or power demands of the thermoelectric converter 110. This ability of the controller 108 to govern parameters such as the output voltage, current, and power ensures a finely tuned and responsive system.

In an embodiment, the controller 108 dynamically modifies the one or more parameters of the DC-to-DC converter 106 to obtain the first level of input power. Such a dynamic control mechanism allows the controller 108 to adapt the operation of the DC-to-DC converter 106 in real-time, ensuring that the modified power aligns precisely with the specified requirement. The modification of input power may involve altering voltage levels, current levels, or other relevant parameters.

Further, the thermoelectric converter 110 may receive the modified input from the DC-to-DC converter 106 and generate the first output. The thermoelectric converter 110 may play an important role in the energy conversion process, specifically configured to receive the modified input power by the DC-to-DC converter 106 and transform it into outputs of distinct thermal characteristics. The thermoelectric converter 110 generates the first output including the first hot output 110a and the first cold output 110b, exhibiting varying temperatures. The thermal duality stems from the inherent thermoelectric effect harnessed within the thermoelectric converter 110. The modified input power passing through initiates a transformation, causing one side of the thermoelectric converter 110 to become notably hotter while the other side of the thermoelectric converter 110 concurrently becomes cooler. Such temperature differential in the first hot output 110a and first cold output 110b enables a more comprehensive evaluation of thermal dynamics. The ability of the thermoelectric converter 110 to produce the first hot output 110a and the first cold output 110b with distinct temperature profiles serves as an asset in addressing the thermal resilience and efficiency of the DUT 104 under different load conditions.

The system 102 may further include the mixer 112. The mixer 112 may receive the first hot output 110a and the first cold output 110b from the thermoelectric converter 110 each characterized by varying temperature. The mixer 112 may be configured to combine the first hot output 110a and the first cold output 110b in such a way that the power dissipation of the system 102 may be minimized by canceling the effect of heat pumping. For an example, the mixer 112 blends the distinct thermal energies (such as the first hot output 110a and the first cold output 110b), thereby minimizing the dissipation of energy into the surrounding environment.

Conventionally, when test loads (passive test load or active test loads) may be employed to the output of the power supplies (such as the DUT 104) the power absorbed by the test loads is converted into heat dissipation in the environment. To overcome such problems, the disclosed system 102 tests the power sources by applying the power to the thermoelectric converter 110 which may pump heat between the first hot output 110a and the first cold output 110b. In such a scenario, the system 102 may utilize the power to generate the temperature difference.

In an embodiment, the thermoelectric converter 110 may control heat flow from the first cold output 110b to the first hot output 110a. This process may prevent localized overheating, thereby reducing thermal stress on components, and maintaining a stable operating temperature throughout the system 102. Further, the mixer 112 may be employed to cancel the effect of such temperature difference by mixing the first hot output 110a and the first cold output 110b, thereby minimizing heat dissipated in the environment.

Further, the mixer 112 mitigates the extremes in temperature, thereby ensuring a controlled and balanced dissipation of heat. This may further ensure the safety of the system 102 by preventing overheating, thereby making the system 102 robust, reliable, and energy efficient. Therefore, the proposed system 102 may facilitate a comprehensive and controlled evaluation of the DUT 104 under diverse load conditions. In an example, the mixer 112 may act as a thermal harmonizer, thereby optimizing the distribution of thermal energy and dissipating heat efficiently. The mixer 112 may further contribute to enhanced efficiency and safety of the entire system by preventing the occurrence of excessive heat that could potentially compromise the integrity of the components.

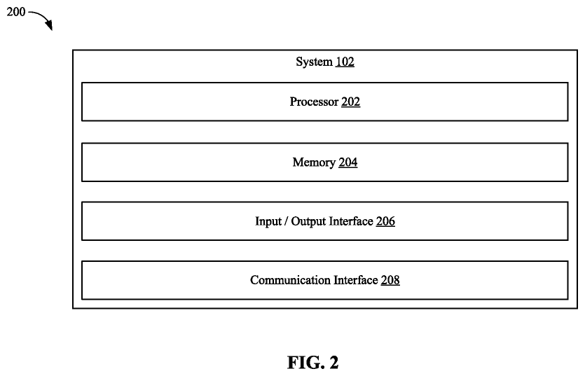

FIG. 2 illustrates a block diagram of the system of FIG. 1, in accordance with an embodiment of the disclosure. FIG. 2 is explained in conjunction with FIG. 1. In FIG. 2, there is shown the block diagram 200 of the system 102. The system 102 may include at least one processor 202 (referred to as a processor 202, hereinafter), at least one non-transitory memory 204 (referred to as a memory 204, hereinafter), an input/output (I/O) interface 206, and a communication interface 208. The processor 202 may be connected to the memory 204, the I/O interface 206, and the communication interface 208 through one or more wired or wireless connections. Although in FIG. 2, it is shown that the system 102 includes the processor 202, the memory 204, the I/O interface 206, and the communication interface 208 however, the disclosure may not be so limiting and the system 102 may include fewer or more components to perform the same or other functions of the system 102.

The processor 202 may interpret input data, make dynamic adjustments to the parameter of the DC-to-DC converter 106, and orchestrate the overall operation of the system 102. Further, the controller 108 may comprise the memory, which may store predefined algorithms, configuration settings, and historical data relevant to the system performance.

The processor 202 may be embodied as one or more of various hardware processing means such as a coprocessor, a microprocessor, a controller, a digital signal processor (DSP), a processing element with or without an accompanying DSP, or various other processing circuitry including integrated circuits such as, for example, an ASIC (application-specific integrated circuit), an FPGA (field programmable gate array), a microcontroller unit (MCU), a hardware accelerator, a special-purpose computer chip, or the like. As such, in some embodiments, the processor 202 may include one or more processing cores configured to perform independently. A multi-core processor may enable multiprocessing within a single physical package. Additionally, or alternatively, the processor 202 may include one or more processors configured in tandem via the bus to enable independent execution of instructions, pipelining, and/or multithreading. Additionally, or alternatively, the processor 202 may include one or more processors capable of processing large volumes of workloads and operations to provide support for big data analysis. In an example embodiment, the processor 202 may be in communication with the memory 204 via a bus for passing information among components of the system 102.

For example, when the processor 202 may be embodied as an executor of software instructions, the instructions may specifically configure the processor 202 to perform the algorithms and/or operations described herein when the instructions are executed. However, in some cases, the processor 202 may be a processor-specific device (for example, a mobile terminal or a fixed computing device) configured to employ an embodiment of the present disclosure by further configuration of the processor 202 by instructions for performing the algorithms and/or operations described herein. The processor 202 may include, among other things, a clock, an arithmetic logic unit (ALU), and logic gates configured to support the operation of the processor 202. The system 102 may be accessed using the communication interface 208 of the system 102. The communication interface 208 may provide an interface for accessing various features and data stored in the system 102.

The memory 204 may be non-transitory and may include, for example, one or more volatile and/or non-volatile memories. In other words, for example, the memory 204 may be an electronic storage device (for example, a computer readable storage medium) comprising gates configured to store data (for example, bits) that may be retrievable by a machine (for example, a computing device like the processor 202). The memory 204 may be configured to store information, data, content, applications, instructions, or the like, for enabling the system 102 to carry out various functions in accordance with an example embodiment of the present disclosure. For example, the memory 204 may be configured to buffer input data for processing by the processor 202. As exemplified in FIG. 2, the memory 204 may be configured to store instructions for execution by the processor 202. As such, whether configured by hardware or software methods, or by a combination thereof, the processor 202 may represent an entity (for example, physically embodied in circuitry) capable of performing operations according to an embodiment of the present disclosure while configured accordingly. Thus, for example, when the processor 202 is embodied as an Application Specific Integrated Circuit (ASIC), Field Programmable Gate Array (FPGA), or the like, the processor 202 may be specifically configured hardware for conducting the operations described herein.

In some example embodiments, the I/O interface 206 may communicate with the system 102 and display the input and/or output of the system 102. As such, the I/O interface 206 may include a display and, in some embodiments, may also include a keyboard, a mouse, a touch screen, touch areas, soft keys, or other input/output mechanisms. In one embodiment, the system 102 may include a user interface circuitry configured to control at least some functions of one or more I/O interface elements such as a display and, in some embodiments, a plurality of speakers, a ringer, one or more microphones and/or the like. The processor 202 and/or I/O interface 206 circuitry including the processor 202 may be configured to control one or more functions of one or more I/O interface 206 elements through computer program instructions (for example, software and/or firmware) stored on a memory 204 accessible to the processor 202. In an embodiment, a user interface may be employed to set up parameters of the active load.

The communication interface 208 may include the input interface and output interface for supporting communications to and from the system 102 or any other component with which the system 102 may communicate. The communication interface 208 may be any means such as a device or circuitry embodied in either hardware or a combination of hardware and software that is configured to receive and/or transmit data to/from a communications device in communication with the system 102. The communication interface 208 may be wired, wireless, or any combination of wired and wireless communication networks, such as cellular, Wi-Fi, internet, local area networks, or the like. In some embodiments, the communication interface may include one or more networks such as a data network, a wireless network, a telephony network, or any combination thereof. It is contemplated that the data network may be any local area network (LAN), metropolitan area network (MAN), wide area network (WAN), a public data network (e.g., the Internet), short range wireless network, or any other suitable packet-switched network, such as a commercially owned, proprietary packet-switched network, e.g., a proprietary cable or fiber-optic network, and the like, or any combination thereof. In addition, the wireless network may be, for example, a cellular network and may employ various technologies including enhanced data rates for global evolution (EDGE), general packet radio service (GPRS), global system for mobile communications (GSM), Internet protocol multimedia subsystem (IMS), universal mobile telecommunications system (UMTS), etc., as well as any other suitable wireless medium, e.g., worldwide interoperability for microwave access (WiMAX), Long Term Evolution (LTE) networks (for e.g. LTE-Advanced Pro), 5G New Radio networks, ITU-IMT 2020 networks, code division multiple access (CDMA), wideband code division multiple access (WCDMA), wireless fidelity (Wi-Fi), wireless LAN (WLAN), Bluetooth, Internet Protocol (IP) data casting, satellite, mobile ad-hoc network (MANET), and the like, or any combination thereof.

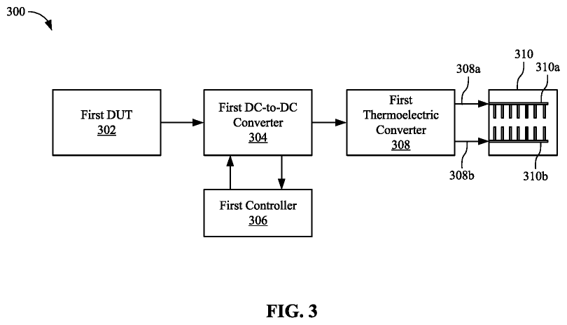

FIG. 3 is a diagram that illustrates an exemplary system for testing the power sources, in accordance with an embodiment of the disclosure. FIG. 3 is explained in conjunction with elements from FIG. 1, and FIG. 2. In FIG. 3 there is shown a block diagram 300 of the system 102 for testing the power sources.

In an embodiment, the system 102 may include a set of DUTs, a set of DC-to-DC converters, a set of controllers, and a set of the thermoelectric converters, without deviating from the scope of the present disclosure. In FIG. 3, the system 102 including a first DUT 302, a first DC-to-DC converter 304, a first controller 306, and a first thermoelectric converter 308 is shown for only exemplary purposes and should not be construed to be limiting the scope of the present disclosure. It may be understood by one of ordinary skill in the art that fewer or a greater number of the DUTs, the DC-to-DC converters, the controllers, and the thermoelectric converters may be equivalently used in the system 102, without deviating from the scope of the present disclosure.

The first DUT 302 of the set of DUTs, and the first DC-to-DC converter of the set of DC-to-DC converters are examples of the DUT 104 and the DC-to-DC converter 106 of FIG. 1, respectively. Similarly, the first controller 306 of the set of controllers, and the first thermoelectric converter 308 of the set of the thermoelectric converters are examples of the controller 108 and the thermoelectric converter 110 of FIG. 1, respectively.

In an embodiment, the first DUT 302 of the set of DUTs includes a power source to provide the input power. Further, the first DC-to-DC converter 304 of the set of DC-to-DC converters may receive the input power and dynamically modify the input power. The first controller 306 of the set of controllers may control one or more parameters of the first DC-to-DC converter 304 and receive feedback from the first DC-to-DC converter 304. Thereafter, the first thermoelectric converter 308 of the set of thermoelectric converters may receive the modified input power from the first DC-to-DC converter 304 and generate a first output of a set of outputs, wherein the first output comprises at least of: a first hot output 308a and a first cold output 308b. Details associated with the DUTs, the DC-to-DC converters, the controllers, and the thermoelectric converters are explained in FIG. 1.

In an embodiment, the system 102 may further include a set of heatsinks 310 connected with the first output of the first thermoelectric converter 308. The set of heatsinks 310 may correspond to a heat exchanger that transfers the heat generated by an electronic or a mechanical device. In such an embodiment, the set of heatsinks 310 may be an example of the mixer 112 of FIG. 1. Further, a first heatsink 310a may receive the first hot output 308a of the first thermoelectric converter 308, and a second heatsink 310b may receive the first cold output 308b of the first thermoelectric converter 308. In an embodiment, a heated air stream and a cooled air stream from the set of heatsinks 310 may be received and combined in the mixer 112 to modify or minimize the power dissipation of the system 102.

In an embodiment, the mixing of the first hot output 308a and the first cold output 308b of the first thermoelectric converter 308 may be done by transference of the heat to air using the set of heatsinks 310 and mixing the heated air stream and the cooled air stream. As shown in FIG. 3, each output of the first thermoelectric converter 308 may be equipped with the set of heatsinks 310. For example, the first hot output 308a may be connected to the first heatsink 310a and the first cold output 308b may be connected to the second heatsink 310b. Such a measure to dissipate the thermal energy generated by the first thermoelectric converter 308 may serve as an effective mechanism for transferring heat from the first hot output 308a to the surrounding environment. The heatsink may absorb and disperse thermal energy efficiently, by connecting it to the first hot output 308a and the first cold output 308b of the first thermoelectric converter 308, thereby allowing the system 102 to minimize the dissipation of heat. Further, this may enhance thermal management within the system 102, contributing to greater efficiency and control over the power dissipation.

The first heatsink 310a and the second heatsink 310b attached to the first hot output 308a and the first cold output 308b, of the first thermoelectric converter 308, respectively, may regulate the temperature of the component. As the power flows through the first thermoelectric converter 308, the first heatsink 310a actively absorbs excess heat from the hot side of the first thermoelectric converter 308. Further, the mixer 112 may receive the heated air stream and cold air stream emanating from the first heatsink 310a and the second heatsink 310b. The mixer 112 actively combines the heated air stream and the cold air stream to create a harmonized air output. In general, excessive power dissipation while testing the power supplies may lead to inefficiencies, increased energy consumption, and potential safety concerns. To overcome such a problem, the proposed system 102 may control the mixer 112 to strategically mitigate temperature differential by blending the heated and cooled air streams, thereby contributing to a more controlled and balanced dissipation of the thermal energy within the system. Such blending of the heated and cooled air streams may further reduce power dissipation effectively, thereby enhancing the efficiency and safety of the system 102.

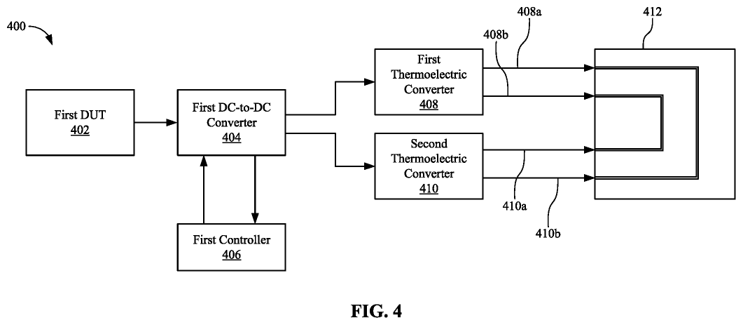

FIG. 4 is a diagram that illustrates another exemplary system for testing a power source, in accordance with an embodiment of the disclosure. FIG. 4 is explained in conjunction with elements from FIG. 1, FIG. 2, and FIG. 3. In FIG. 4 there is shown a block diagram 400 of the system 102 for testing the power sources.

In an embodiment, a first DUT 402 of the set of DUTs includes a power source to provide the input power. Further, a first DC-to-DC converter 404 of the set of DC-to-DC converters may receive the input power and dynamically modify the input power. A first controller 406 of the set of controllers may dynamically modify or control one or more parameters of the first DC-to-DC converter 404 to obtain a first level of the input power and receive feedback from the first DC-to-DC converter 404. Thereafter, a first thermoelectric converter 408 of the set of thermoelectric converters may receive the modified input power from the first DC-to-DC converter 404 and generate a first output of a set of outputs, wherein the first output comprises at least of: a first hot output 408a and a first cold output 408b. Details associated with the DUTs, the DC-to-DC converters, the controllers, and the thermoelectric converters are explained in FIG. 1.

In an embodiment, the system 102 may further include a second thermoelectric converter 410 of the set of thermoelectric converters to generate a second output comprising at least of: a second hot output 410a and a second cold output 410b. Further, the first hot output 408a of the first thermoelectric converter 408 is connected to the second cold output 410b of the second thermoelectric converter 410, and the first cold output 408b of the first thermoelectric converter 408 is connected to the second hot output 410a of the second thermoelectric converter 410.

The first thermoelectric converter 408 and the second thermoelectric converter 410 are examples of the thermoelectric converter 110 as explained in FIG. 1. The first thermoelectric converter 408 and the second thermoelectric converter 410 may enhance the thermal dynamics with the system 102, providing a sophisticated and efficient means of managing the heat generated during the process. According to the present disclosure, the first thermoelectric converter 408 and the second thermoelectric converter 410 may represent a strategic design choice to further optimize the performance of the system 102. The first thermoelectric converter 408 and the second thermoelectric converter 410 may be a device that leverages the thermoelectric effect to convert electrical energy into the thermal energy.

In an embodiment, the mixing of the first hot output 308a and the first cold output 308b of the first thermoelectric converter 308 may be done by transferring heat through solid conductive media (metal). It is to be noted that the mixing of the first hot output 308a and the first cold output 308b of the first thermoelectric convertor 308 may be done by employing other modern thermal transfer methods such as, but not limited to, phase change materials or heat pipes without any deviation from the scope of the present disclosure. As shown in FIG. 4, the mixer 412 may be configured to connect the first hot output 408a of the first thermoelectric converter 308 and the second cold output 410b of the second thermoelectric converter 410 forming the close loop thermal circuit. Simultaneously, the mixer 112 may connect the first cold output 408b of the first thermoelectric converter 408 with the second hot output 410a of the second thermoelectric converter 410. The interconnected arrangements establish a thermal equilibrium, where heat circulates between the first thermoelectric converter 408 and the second thermoelectric converter 410, creating a continuous flow of thermal energy.

According to the present disclosure, the configuration holds significant implications for the overall efficiency of the system 102. By connecting the hot output of one the thermoelectric converter to the cold output of another thermoelectric converter, and vice versa, a counter-current heat exchange mechanism is established. This counter-current exchange enables the transfer of thermal energy from the hotter side to the cooler side, mitigating temperature differential and enhancing overall thermal management.

In an embodiment, the interconnection of the first thermoelectric converter 408 and the second thermoelectric converter 410 introduce a level of synergy that optimizes the temperature differential within the system. As a higher load power flows through the first thermoelectric converter 408 and the second thermoelectric converter 410, it is beneficial to group the thermoelectric converters in pairs having the hot output and the cold output cross connected, thereby reducing the size of required heatsinks. Such configuration may enable a continuous exchange of thermal energy to ensure a balanced distribution of heat. This, in turn, contributes to a stable and controlled testing environment, preventing excessive heat build-up that could potentially impact the reliability and safety of the system 102.

Moreover, the configuration aligns with the principle of energy conservation, as it maximizes the utilization of thermal energy generated during the testing output of the power source process. The interconnected thermoelectric converters create a closed-loop system where thermal energy is efficiently circulated and exchanged, minimizing the power dissipation into the environment, and enhancing the overall sustainability of the system 102.

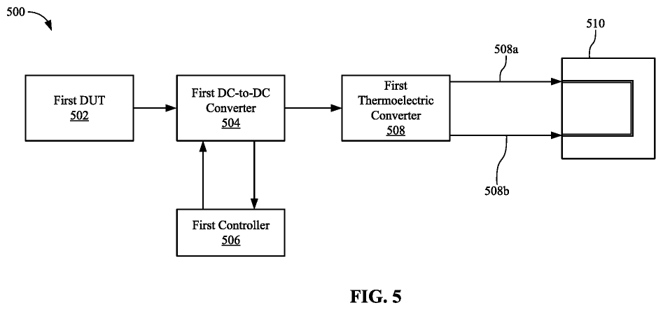

FIG. 5 is a diagram that illustrates an exemplary system for testing a power source, in accordance with an embodiment of the disclosure. FIG. 5 is explained in conjunction with elements from FIG. 1, FIG. 2, FIG. 3, and FIG. 4. In FIG. 5 there is shown a block diagram 500 of the system 102 for testing the power sources.

In an embodiment, a first DUT 502 of the set of DUTs includes a power source to provide the input power. Further, a first DC-to-DC converter 504 of the set of DC-to-DC converters may receive the input power and dynamically modify the input power. A first controller 506 of the set of controllers may control one or more parameters of the first DC-to-DC converter 504 and receive feedback from the first DC-to-DC converter 504. Thereafter, a first thermoelectric converter 508 of the set of thermoelectric converters may receive the modified input power from the first DC-to-DC converter 504 and generate a first output of a set of outputs, wherein the first output comprises at least of: a first hot output 508a and a first cold output 508b. Details associated with the DUTs, the DC-to-DC converters, the controllers, and the thermoelectric converters are explained in FIG. 1.

In an embodiment, the mixing of the first hot output 508a and the first cold output 508b of the first thermoelectric converter 508 may be done by pumping a thermally conductive liquid between the first hot output 508a and the first cold output 508b. As shown in FIG. 5, a pump 510 may be configured to circulate (or pump) the thermally conductive liquid between the first hot output 508a and the first cold output 508b. The thermally conductive liquid circulation provides thermal management. The pump 510 facilitates the transfer of thermal energy between the first hot output 508a and the first cold output 508b of the first thermoelectric converter 508 by continuously circulating the thermally conductive liquid. As the thermally conductive liquid transfer between the first hot output 508a and the first cold output 508b, the pump 510 efficiently carries heat from the first hot output 508a to the first cold output 508b. Such dynamic liquid circulation by pump 510 may cancel the temperature difference between the first hot and first cold output and reduce the dissipation of heat into the environment.

In one embodiment, the power required for the operation of the pump 510 may be sourced from the power supplied by the first DUT 502 through the first DC-to-DC converter 504. This may correspond to another form of non-dissipative loading as it is mechanical energy. In some embodiment, the system 102 may incorporate an external power source, such as an AC power source, to ensure the optimal functioning of the pump 510.

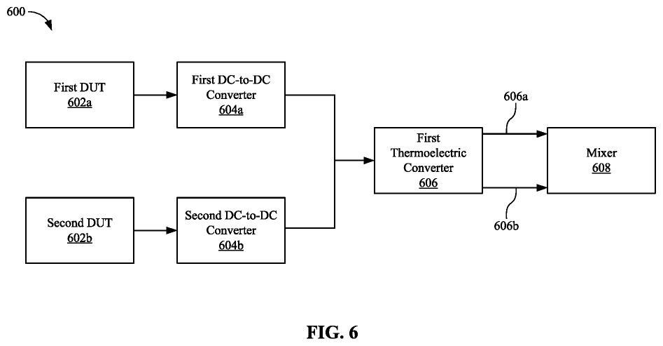

FIG. 6 is a diagram that illustrates another exemplary system for testing the power sources, in accordance with an embodiment of the disclosure. FIG. 6 is explained in conjunction with elements from FIG. 1, FIG. 2, FIG. 3, FIG. 4, and FIG. 5. In FIG. 6 there is shown a block diagram 600 of the system 102 for testing the power sources.

In an embodiment, the set of DC-to-DC converters loading the set of DUTs (multiple power sources) or different outputs of the same power supply with their outputs delivering power to a first thermoelectric converter 606. In an example, the system 102 may include each of the set of DUTs connected to each of the set of DC-to-DC converters to convert the suitable level of voltage for the set of thermoelectric converters. Further, the set of outputs of each of the set of thermoelectric converters may be connected to a mixer 608 to minimize heat dissipation into the environment.

As shown in FIG. 6, the system 102 may include a first DUT 602a and a second DUT 602b, serving as examples of power sources and providing the input power as explained in FIG. 1. Further the system 102 may include a first DC-to-DC converter 604a and a second DC-to-DC converter 604b which is same as the set of DC-to-DC converter 106 as explained in FIG. 1. Further the first DUT 602a may provide the input power to the first DC-to-DC converter 604a, and the second DUT 602b may provide the input power to the second DC-to-DC converter 604b. The first controller, and a second controller may dynamically modify the one or more parameters for the first DC-to-DC converter 604a and the second DC-to-DC converter 604b, respectively. Such dynamic adjustment ensures that the modified input power from the both DC-to-DC converters is suitably aligned for the first thermoelectric converter 606.

Each controller of the set of controllers may control the one or more parameters of the first DC-to-DC converter 604a and second DC-to-DC converter 604b and receive feedback from the first DC-to-DC converter 604a and the second DC-to-DC converter 604b. The first thermoelectric converter 606 may receive the modified power and generate a first hot output 606a and a first cold output 606b. Further, the mixer 608 may receive the first hot output 606a and the first cold output 606b and combine the first hot output 606a and the first cold output 606b to minimize the power dissipation of the system by cancelling the effect of heat pumping.

In an embodiment, the set of controllers may further provide a real-time data associated with one or more performance metrics of the set of DUTs, the set of DC-to-DC converters, the set of thermoelectric converters, and the mixer. In an example, the system 102 may further include a monitoring unit seamlessly integrated into the framework. The monitoring unit may serve as a comprehensive observer, maintaining a communicative link with the set of controllers and providing real-time data on the performance metrics of key elements within the system 102, including the first DC-to-DC converter 304, the first thermoelectric converter 308, the mixer 319, and the first DUT 302.

In an embodiment, the monitoring unit may be connected to the first controller 306 to establish a continuous flow of information, creating a dynamic feedback loop that may enrich the system's adaptability and responsiveness. By actively collecting and relaying data, the monitoring unit may offer a panoramic view of the entire process. Real-time insights into the performance metrics of the first DC-to-DC converter 304 enable precise adjustment to ensure optimal energy conversion. Simultaneously, the monitoring unit scrutinizes the first thermoelectric converter 308, evaluating its thermal dynamics and contributing valuable data for a nuanced assessment of the load power's impact. Additionally, the monitoring unit extends its oversight to the mixer 112 ensuring that the harmonization and modification of thermal outputs align with the desired parameters. The monitoring unit also monitors the performance of the first DUT 302, offering real-time feedback on its electrical characteristics and responses to varying loads. The intelligent control mechanism, adept at dynamic adjustments, enhances the precision and may also contribute to the system's overall efficiency and reliability in evaluating the performance of active devices under diverse conditions. Further, such monitoring capability ensures that the environment accurately mirrors the real-world scenarios, offering a more realistic and robust evaluation.

In an embodiment, the first DC-to-DC converter 304 encompasses the optimization of power characteristics, including the overall power output of the first DUT 302. Such adaptability becomes particularly important when dealing with the diverse devices, each with the unique power demands. The first DC-to-DC converter 304 efficiently converts input power to modified input power, tailored to the specific need of the DUT 104.

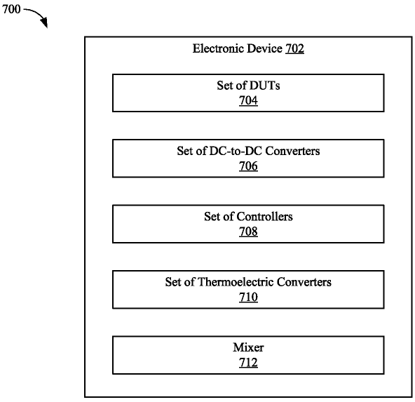

FIG. 7 illustrates a block diagram 700 of an electronic device 702 for testing a set of DUTs, in accordance with some embodiment of the disclosure. FIG. 7 is explained in conjunction with elements from FIG. 1, FIG. 2, FIG. 3, FIG. 4, FIG. 5, and FIG. 6.

The electronic device 702 includes a set of DUTs 704, a set of DC-to-DC converters 706, a set of controllers 708, a set of thermoelectric converters 710, and a mixer 712. The electronic device 702 may be used for testing various power sources with reduced power dissipation. The first DUT from the set of DUTs 704 includes a power source to provide an input power. The electronic device 702 comprises the first DC-to-DC converter of the set of DC-to-DC converters 706. The first DC-to-DC converter receives the input power and dynamically modifies the voltage level of the input power. Further, the electronic device 702 includes a first controller of the set of controllers 708 to control one or more parameters of the first DC-to-DC converter and receives feedback from the first DC-to-DC converter.

Further, the electronic device 702 comprises the set of thermoelectric converters 710 to receive the modified input power from the set of DC-to-DC converters 706 and generate a first output of a set of outputs. The first output comprises at least: a first hot output and a first cold output. Further, the electronic device 702 comprises a mixer to receive the first output and combine the first hot output and the first cold output to modify the power dissipation of the electronic device 702.

In an embodiment, the electronic device 702 may correspond to a device that may be employed to test power sources (such as the set of DUTs 704). The set of DUTs 704 may be connected to the set of DC-to-DC converters 706 (for example, a linear regulator), which may be a device that converts the voltage from the set of DUTs 704 to a level that suits the operation of the set of thermoelectric converters 710. The set of DC-to-DC converters 706 may be controlled by the set of controllers 708, which is a device that monitors and adjusts the parameters of the set of the set of DC-to-DC converters 706, such as output voltage, current, and power. The set of controllers 708 also receives feedback from the set of DC-to-DC converters 706 about its performance and status. Further, the set of DC-to-DC converters 706 sends power to the set of thermoelectric converters 710, which is a device that uses the thermoelectric effect to convert electrical energy into thermal energy. The thermoelectric converter may have two outputs, a hot output, and a cold output. In an example, the hot side becomes hotter, and the cold side becomes colder as power flows through the thermoelectric converter. The hot and cold outputs of the thermoelectric converter are connected to a mixer, which is a device that combines the thermal energy from both sides and the result of mixing the hot and cold outputs may be dissipated into the environment. As most power is used for the thermal conversion and the mixer 712 cancels the temperature difference the overall power dissipation in the environment is minimized.

Further, the electronic device 702 may be connected to an AC power source that provides input power to various electronic devices such as the set of controllers 708 and the mixer 712 for performing operations. In an embodiment, the electronic device 702 may include the AC power source. In another embodiment, an external AC power source may be employed to power the internal circuitry of active load via a housekeeping power supply. In another embodiment, the internal circuitry may be powered by auxiliary outputs of the set of DC-to-DC converters 706. In an embodiment, the set of DUTs 704 may supply the necessary energy to drive the entire system 102, thereby providing a comprehensive evaluation of the performance of the set of DUTs 704. The characteristics of the input power such as voltage and current may set baseline conditions for the subsequent stages of the process for testing of a set of DUTs 704.

In another embodiment, a system for testing a DUT is disclosed. The system includes a first DUT of the set of DUTs including a power source for providing an input power. The system may further include a first DC-to-DC converter of the set of DC-to-DC converters to receive the input power from the first and dynamically modify or convert a voltage level of the input power to a first level of the input power. The first level of the input power may correspond to a suitable voltage level based on the specification of the first thermoelectric converter. Further, the system may be a first controller of a set of controllers to control one or more parameters of the first DC-to-DC converters and receive feedback from the first DC-to-DC converter. The one or more parameters may include but are not limited to voltage level, current level, and load resistance. The system may further include a first thermoelectric converter of a set of thermoelectric converters to receive the first level of the input power from the first DC-to-DC converter and generate first output comprises at least: a first hot output and a first cold output. The first thermoelectric converter pumps heat from the first cold output to the first hot output. Further, the system may include a mixer to receive the first hot output, and the first cold output, and combine the first hot output and the first cold output to minimize power dissipation of the system by cancelling the effect of heat pumping.

Many modifications and other embodiments of the inventions set forth herein will come to mind to one skilled in the art to which these inventions pertain having the benefit of the teachings presented in the foregoing descriptions and the associated drawings. It is to be understood that the inventions are not to be limited to the specific embodiments disclosed and that modifications and other embodiments are intended to be included within the scope of the appended claims. Moreover, although the foregoing descriptions and the associated drawings describe example embodiments in the context of certain example combinations of elements and/or functions, it should be appreciated that different combinations of elements and/or functions may be provided by alternative embodiments without departing from the scope of the appended claims. In this regard, for example, different combinations of elements and/or functions than those explicitly described above are also contemplated as may be set forth in some of the appended claims. Although specific terms are employed herein, they are used in a generic and descriptive sense only and not for purposes of limitation.

1. A system, comprising:
a first device under test (DUT) of a set of DUTs comprising a power source to provide an input power;
a first DC-to-DC converter of a set of DC-to-DC converters to receive the input power and dynamically modify the input power;
a first controller of a set of controllers to control one or more parameters of the first DC-to-DC converter and receive feedback from the first DC-to-DC converter;
a first thermoelectric converter of a set of thermoelectric converters to receive the modified input power from the first DC-to-DC converter and generate a first output of a set of outputs, wherein the first output comprises at least of: a first hot output and a first cold output; and
a mixer to receive the first output and combine the first hot output and the first cold output to cancel a temperature difference between the first hot output and the first cold output and minimize power dissipated by the system into an environment.

2. The system of claim 1, wherein the first thermoelectric converter further controls heat flow from the first cold output to the first hot output.

3. The system of claim 1, wherein the system further comprises of a set of heatsinks connected with the first output of the first thermoelectric converter.

4. The system of claim 3, wherein the mixer further receives a heated air stream and a cooled air stream from the set of heatsinks and combines the heated air stream and cooled air stream to modify the power dissipation of the system.

5. The system of claim 1, wherein the system further comprises a second thermoelectric converter of the set of thermoelectric converters to generate a second output comprising at least of: a second hot output and a second cold output.

6. The system of claim 5, wherein the first hot output of the first thermoelectric converter is connected to the second cold output of the second thermoelectric converter, and the first cold output of the first thermoelectric converter is connected to the second hot output of the second thermoelectric converter.

7. The system of claim 1, wherein the first DC-to-DC converter dynamically modifies a voltage level of the input power to a first level of the input power based on specification of the first thermoelectric converter.

8. The system of claim 1, wherein the first controller dynamically modifies the one or more parameters of the first DC-to-DC converter to obtain a first level of the input power.

9. The system of claim 1, wherein the first DUT corresponds to a DC power source for providing a DC input power.

10. The system of claim 1, wherein the first DUT corresponds to an AC power source for providing an AC input power.

11. The system of claim 10, wherein the system further comprises an AC-to-DC converter to convert AC input power to DC input power.

12. The system of claim 1, wherein the set of controllers further provides a real-time data associated with one or more performance metrics of the set of DUTs, the set of DC-to-DC converters, the set of thermoelectric converters, and the mixer.

13. An electronic device, comprising:
a first device under test (DUT) of a set of DUTs comprising a power source to provide an input power;
a first DC-to-DC converter of a set of DC-to-DC converters to receive the input power and dynamically modify the input power;
a first controller of a set of controllers to control one or more parameters of the first DC-to-DC converter, and receive feedback from the first DC-to-DC converter;
a first thermoelectric converter of a set of thermoelectric converters to receive the modified input power from the first DC-to-DC converter and generate a first output of a set of outputs, wherein the first output comprises at least of: a first hot output and a first cold output; and
a mixer to receive the first output and combine the first hot output and the first cold output to modify power dissipation of the electronic device.

14. The electronic device of claim 13, wherein the first thermoelectric converter further controls heat flow from the first cold output to the first hot output.

15. The electronic device of claim 13, wherein the electronic device further comprises of a set of heatsinks connected with the first output of the first thermoelectric converter.

16. The electronic device of claim 15, wherein the mixer further receives a heated air stream and a cooled air stream from the set of heatsinks and combines the heated air stream and cooled air stream to modify the power dissipation of the electronic device.

17. The electronic device of claim 13, wherein the electronic device further comprises a second thermoelectric converter of the set of thermoelectric converters to generate a second output comprising at least of: a second hot output and a second cold output.

18. The electronic device of claim 17, wherein the first hot output of the first thermoelectric converter is connected to the second cold output of the second thermoelectric converter, and the first cold output of the first thermoelectric converter is connected to the second hot output of the second thermoelectric converter.

19. The electronic device of claim 13, wherein the first DC-to-DC converter dynamically modifies a voltage level of the input power to a first level of the input power based on specification of the first thermoelectric converter.

20. A system, comprising:
a first device under test (DUT) of a set of DUTs comprising a power source to provide an input power;
a first DC-to-DC converter of a set of DC-to-DC converters to receive the input power and dynamically modify a voltage level of the input power to a first level of the input power;
a first controller of a set of controllers to control one or more parameters of the first DC-to-DC converters and receive feedback from the first DC-to-DC converter;
a first thermoelectric converter of a set of thermoelectric converters to receive the first level of the input power from the first DC-to-DC converter and generate a first output comprising at least a first hot output and a first cold output, wherein the first thermoelectric converter pumps heat from the first cold output to the first hot output; and
a mixer to receive the first hot output, and the first cold output, and combine the first hot output and the first cold output to minimize power dissipation of the system by cancelling the effect of heat pumping.
